(19) United States
(12) Patent Application Publication
(10) Pub. No.: US 2005/0046457 A1
(43) Pub. Date: Mar. 3, 2005

(54) Method and system for power supply control using a fixed-frequency pulse width modulation control circuit

(76) Inventor: Jason C. Pierce, Dahlonega, GA (US)

Correspondence Address: ARRIS INTERNATIONAL, INC, 3871 LAKEFIELD DRIVE, SUWANEE, GA, 30024, US

(21) Appl. No.: 10/933,044

(22) Filed: Sep. 2, 2004

Related U.S. Application Data
(60) Provisional application No. 60/499,407, filed on Sep. 2, 2003.

(51) Int. Cl. H03L 7/06

(52) U.S. Cl. 327/175

(57) ABSTRACT

A voltage divider splits the input voltage to be regulated between the input voltage node and the dead time pin of a TL494 voltage regulator. Thus, the duty cycle limit varies in inverse proportion to the input voltage node. Accordingly, the duty cycle percentage limit is reduced when the input voltage to be regulated is a relatively high voltage as compared to use in a circuit where the voltage to be regulated is comparatively low with respect to the input voltage range specification for the supply.

A small signal transistor is connected in series with the output driver(s) of the TL494 to achieve a safe shutdown condition of the TL494, thereby preventing the output driver(s) from turning on the main power transistor in the absence of adequate V_{cc} voltage.

### CROSS REFERENCE TO RELATED APPLICATION

This application claims priority under 35 U.S.C. 119(e) to the filing date of Pierce, et. al., U.S. provisional patent application No. 60/499,407 entitled “Method for power down and dead time control of TL494,” which has a filing date of Sep. 2, 2003, and is incorporated herein by reference in its entirety.

### FIELD OF THE INVENTION

The present invention relates generally to electric power supply circuits for electronic devices, and more particularly to a supply that uses a pulse-width modulation control circuit for output voltage regulation.

### BACKGROUND

Practically all electronic devices require a power supply that provides a regulated output power. The TL494 integrated circuit (“IC” ), manufactured by Texas Instruments, Inc. and many others (On Semiconductor, Fairchild Semiconductor, Unisonic Technologies, Advanced Analog Circuits, etc) is a common IC used by many equipment manufacturers. The TL494 is typically used as the basis for a pulse width modulation voltage regulator. The TL494 includes a dead-time pin that receives a voltage and provides a duty cycle limit that is based on the voltage received at the dead-time pin. The higher the voltage applied to the dead-time pin, the lower the duty cycle limit, the lower the applied voltage the higher the duty cycle limit.

As shown in FIG. 1, The TL494 is typically used in a circuit with a voltage divider splitting a voltage with respect to ground between a reference pin, denoted V_{ref}, and the dead-time pin. The reference pin provides a constant output voltage, thus, when the voltage divider splits the voltage between the reference voltage pin and the dead-time pin, the duty cycle limit is a percentage that remains constant regardless of the input voltage. For a given output voltage and load current, a lower duty cycle is needed with a higher input voltage. Therefore, it is desirable to set a duty cycle limit that is based on the input voltage. Accordingly, at lower input voltages, higher duty cycles are permitted. At higher input voltages, lower duty cycles are permitted. This provides more protection under fault conditions than simply having a duty cycle limit that is constant regardless of the input voltage. With the existing method however, the duty cycle limit is a fixed percentage regardless of the input voltage. At the maximum specified input voltage, excessive duty cycles can occur during fault conditions making damage to components of the circuit being supplied along with components in the power supply itself more likely.

With respect to power down of the TL494 , the C1 and C2 pins of the TL494 are the collectors of the drive transistors and E1 and E2 are the emitters of the drive transistors. An enable circuit can disconnect the V_{cc} pin of the controller from the input voltage. This can be used for special power savings modes. However, a problem may arise when the TL494 is shutdown. With at least some manufacturers versions of the TL494 the output transistors turn on right before power is completely removed from the device. This is normally not a problem—if the controller doesn't have an input voltage (this will be referred to as V_{cc}) neither does the converter (referred to as Vᵢₙ). For powering down the TL494, it is desirable to remove V_{cc} (a low current path), but keep Vᵢₙ at the converter (a high current path). This allows the converter to be shutdown using small signal components instead of a device capable of carrying the entire input current of the converter. However, this results in the previously discussed situation where the TL494 output transistors momentarily latch ‘on’ during shutdown. This will turn on the main power switch (transistor) and essentially create a DC short circuit. The topology considered for this discussion will be a buck/boost. In this case, the short will be from Vᵢₙ to ground through the buck/boost switch and its related inductor. The buck/boost switch and related inductor are known in the art. This results in the sinking of current from the voltage signal to be regulated, thus wasting power and potentially damaging the main power switch, inductor, and input power supply from excessive current.

Therefore, there is a need in the art for a circuit using a TL494-based regulator that provides a duty cycle limit that is based on the input voltage.

Furthermore, there is a need in the art for a means for ensuring that the main power switch remains off when the TL494 is being powered-down.

### SUMMARY

An aspect uses a voltage divider to split the input voltage to be regulated between the input voltage node and the dead time pin. The voltage divider is disconnected from the V_{ref} pin and is instead connected to the input voltage node. Thus, the duty cycle limit varies in inverse proportion to the input voltage node. Accordingly, the duty cycle percentage limit is reduced when the input voltage to be regulated is a relatively high voltage as compared to use in a circuit where the voltage to be regulated is comparatively low with respect to the input voltage range specification for the supply.

An added advantage is that because the V_{ref}, which typically has a 5% tolerance, is not used as the reference for determining the duty cycle percentage limit, the duty cycle limit can be set 5% closer to the desired maximum.

A small signal transistor may be added around the TL494 to achieve a safe shutdown condition. The transistor is connected in series with the output driver(s) of the TL494. This additional transistor prevents the output driver(s) of the TL494 from turning on the main power transistor on the absence of adequate V_{cc} voltage.

### BRIEF DESCRIPTION OF THE DRAWINGS

FIG. 1 illustrates the connection of components typically used in the art for regulating a voltage with a fixed percent duty cycle limit using a TL494 PWM.

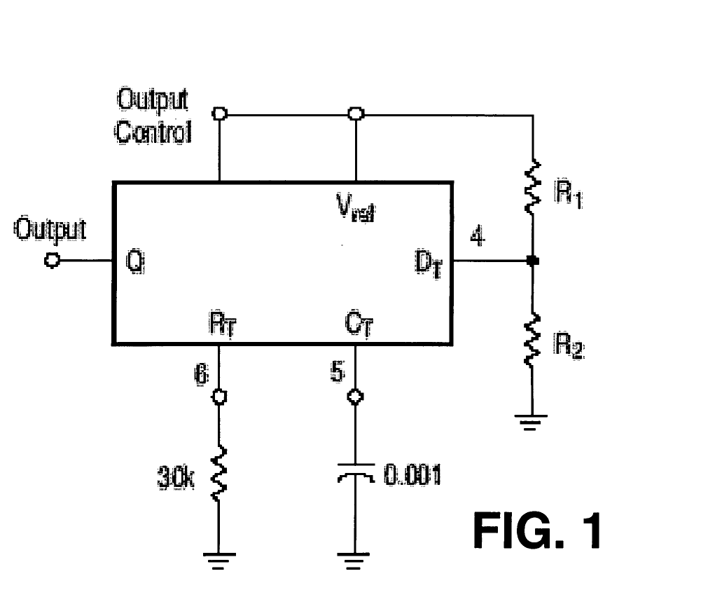

FIG. 2 illustrates a connection of components using a TL494 where the duty cycle limit is based on the input voltage to be regulated.

FIG. 3 illustrates a connection of components that prevents the main power transistor from being turned on in the absence of a V_{cc} voltage to the TL494. The example shown is a buck/boost. Other topologies will be similar.

### DETAILED DESCRIPTION

As a preliminary matter, it will be readily understood by those persons skilled in the art that the present invention is susceptible of broad utility and application. Many methods, embodiments and adaptations of the present invention other than those herein described, as well as many variations, modifications, and equivalent arrangements, will be apparent from or reasonably suggested by the present invention and the following description thereof, without departing from the substance or scope of the present invention.

Accordingly, while the present invention has been described herein in detail in relation to preferred embodiments, it is to be understood that this disclosure is only illustrative and exemplary of the present invention and is made merely for the purposes of providing a full and enabling disclosure of the invention. This disclosure is not intended nor is to be construed to limit the present invention or otherwise to exclude other embodiments, adaptations, variations, modifications and equivalent arrangements, the present invention being limited only by the claims appended hereto and the equivalents thereof.

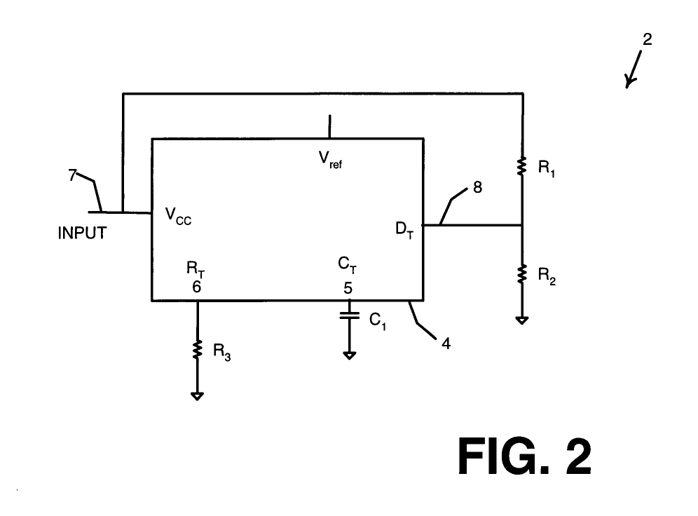

Turning now to the figures, FIG. 2 illustrates a circuit configuration for a power supply circuit 2 based on a TL494 PWM control IC 4. A voltage divider, comprising R1 and R2 splits voltage with respect to ground between the input voltage node 7 and dead-time control pin 8. Thus, as the input voltage to be regulated at pin 7 increases, the duty cycle percentage limit decreases because the voltage at pin 8 increases. As known in the art, the higher the voltage at dead-time control pin the lower the duty cycle percentage limit. In addition, duty cycle limit is not dependant on the voltage at V_{REF}, which can typically vary up to 5%. Thus, the input voltage to be regulated, along with the values of R1 and R2 set the duty cycle limit.

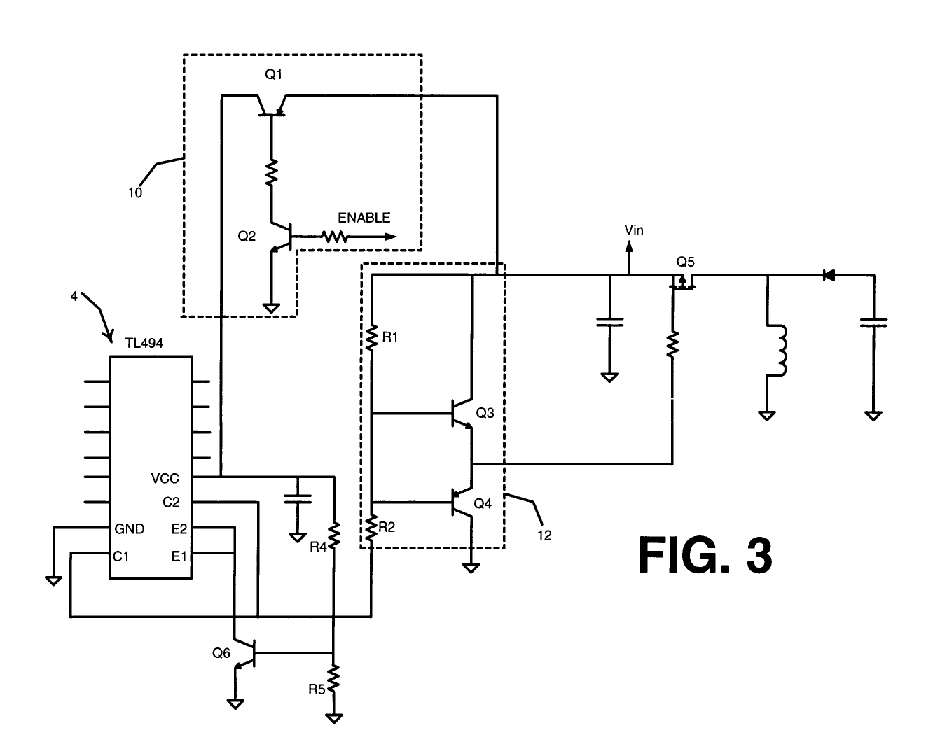

Turning now to FIG. 3, a small signal NPN (Q6) is added to lock out the TL494 driver(s) when V_{CC} is removed from the TL494 PWM controller 4. The base current of NPN Q6 is supplied from the V_{cc} node of the TL494 through resistor divider R4/R5. The V_{CC} of the TL494 pin is controlled by enable circuit 10, and the input voltage Vᵢₙ. Values for R4 and R5 are chosen so that when Vᵢₙ decays to a point where the TL494 enters an undefined mode of operation, transistor Q6 is turned off effectively floating the output driver(s) of the TL494. This keeps the input and output of totem-poll circuit 12 high, which in turn keeps Q5 turned off. When V_{CC} is zero, the output transistors of TL494 controller 4 stop sinking current and no additional power is dissipated in R2.

These and many other objects and advantages will be readily apparent to one skilled in the art from the foregoing specification when read in conjunction with the appended drawings. It is to be understood that the embodiments herein illustrated are examples only, and that the scope of the invention is to be defined solely by the claims when accorded a full range of equivalents.

1. A circuit for controlling the output duty cycle limit of a fixed-frequency pulse width modulation voltage regulator based on an input voltage comprising a divider for dividing a voltage signal present at an input voltage node between the input voltage node and a dead time control node.

2. The circuit of claim 1 wherein the divider is a voltage divider.

3. The circuit of claim 2 wherein the divider comprises a first resistor connected between the input voltage node and the dead time control node and a second resistor connected between the dead time control node and ground.

4. The circuit of claim 1 wherein the voltage regulator circuit includes a TL 494 integrated circuit.

5. A circuit for powering-down a fixed-frequency pulse width modulation voltage regulator circuit based on the voltage difference between a V_{cc} pin and an input voltage node comprising:
an enable circuit connected between the input voltage node and the V_{cc} pin;
a totem-pole circuit connected between the input/output node and an output of the regulator, wherein the totem-pole circuit includes an NPN transistor having its emmiter connected to the collector of a PNP transistor, the totem-pole circuit further having a first resistor and a second resistor corresponding to the NPN and PNP transistors respectively, wherein the first resistor is connected across the base and collector of the NPN transistor, the collector of the NPN transistor being connected to the input voltage node, and the second resistor is connected from the base of the PNP transistor to the output of the regulator;
an NPN transistor, having its emitter connected to ground, its collector connected to the base of E1 and E2 pins of the regulator circuit, and its gate connected to the V_{cc} pin through a resistor divider from the V_{cc} pin to ground.

6. The circuit of claim 5 wherein an output of the enable circuit is connected to the supply voltage node.

7. The circuit of claim 5 wherein the regulator circuit includes a TL494 integrated circuit.
